(19) United States
(12) Patent Application Publication
(10) Pub. No.: US 2007/0262437 A1
(43) Pub. Date: Nov. 15, 2007

(54) Semiconductor device with temperature cycle life improved

(75) Inventors: Koji Hosokawa, Tokyo (JP); Yuji Watanabe, Tokyo (JP)

Correspondence Address: Paul J. Esatto, Jr.;Scully, Scott, Murphy & Presser, 400 Garden City Plaza, Garden City, NY, 11530, US

(73) Assignee: Elpida Memory, Inc., Tokyo (JP)

(21) Appl. No.: 11/801,069

(22) Filed: May 8, 2007

(30) Foreign Application Priority Data
May 12, 2006 (JP) 2006-133663

(51) Int. Cl. H01L 23/02

(52) U.S. Cl. 257/686

(57) ABSTRACT

The semiconductor device of the invention has a motherboard 3, a lower package 2 mounted on the motherboard 3, and an upper package 1 mounted on the lower package 2 via intermediate terminals 11. Edge portions, in a marginal area of the lower package 2, with which the intermediate terminals 11 overlap are in contact with the motherboard 3.

This application claims priority to prior Japanese application JP 2006-133663, the disclosure of which is incorporated herein by reference.

### BACKGROUND OF THE INVENTION

The present invention relates to a semiconductor device in which a plurality of packages is mounted on a motherboard.

Semiconductor devices for large-capacity and small-sized memory modules and the like are now in great demand and a thin semiconductor device having a stacked-package configuration is expected to be developed. Examples of such stacked-package semiconductor devices include a stacked-chip and stacked-package semiconductor devices. In particular, the stacked-package semiconductor device is expected to be developed because it enables suppression of a loss of yield caused by faulty chips (semiconductor chips) by enabling good packages to be selected to be combined by stacking.

For example, one in which two packages are stacked to form a stacked-package semiconductor device has a motherboard, a lower package connected to a land of the motherboard via lower terminals and an upper package connected to a land of the lower package via intermediate terminals. The lower and upper packages have interposers and chips mounted on the interposers via mounting members, respectively. Each of the chips mounted on the corresponding interposer may be sealed by sealing resin in the lower and upper packages.

A problem has been encountered with the semiconductor device constructed as described above relating to its life in a packaging temperature cycle of the intermediate terminals. The packaging temperature cycle life refers to the life of the semiconductor device in which the packages are mounted on the motherboard when tested by a temperature cycle test. The packaging temperature cycle life is an important parameter in guaranteeing a temporal reliability of the semiconductor device to customers.

Because the package is a complex of non-organic and organic materials, stress and deformation at each part thereof can occur with changes in temperature. Specifically, the stress caused in the connecting terminals generates plastic deformation (plastic strain) of the terminals. The plastic strain accumulates when the temperature is changed repeatedly. The accumulated plastic strain advances rapture of the terminals, breaking the terminals in the end.

Attention is given to the intermediate terminals when warping of the lower and upper packages is large. The stress caused in the intermediate terminals correlates with a degree of warping of the semiconductor device. A degree of plastic strain also correlates to the stress caused in the intermediate terminals. The degree of warping is large at an edge portion of the semiconductor device, so that the degree of plastic strain of the intermediate terminal is large at the edge portion of the semiconductor device. That is, the rapture of the intermediate terminal at the edge portion of the semiconductor device advances quickly and the packaging temperature cycle life is shortened.

Japanese Patent No. 3168987 discloses a stacked-package semiconductor device. The semiconductor device has a surface packaging jig between a motherboard and an edge portion of an interposer such that packages are solidly mounted on the motherboard even if the packages becomes warped. That is, in the semiconductor device disclosed in the Japanese Patent No. 3168987, a jig is provided having a height adjusting mechanism that keeps a distance between terminals of the lower package and the motherboard constant. The height adjusting mechanism realizes a solid mountability even if the packages become warped.

However, a part where the jig contacts the interposer of the lower package is limited to an edge of the interposer due to the height adjusting function of the jig in the configuration disclosed in Japanese Patent No. 3168987. Therefore, the warping of the intermediate terminal portion cannot be fully suppressed. As a result, the packaging temperature cycle life of the intermediate terminal is shortened.

### SUMMARY OF THE INVENTION

Accordingly, it is an object of the present invention to provide a semiconductor device in which a plurality of packages is mounted on a motherboard and whose packaging temperature cycle life is improved.

According to an aspect of the invention, there is provided a semiconductor device comprising a motherboard, a lower package mounted on the motherboard, and an upper package mounted on the lower package via intermediate terminals. An edge portion, with which the intermediate terminals overlaps, in a marginal area of the lower package is in contact with the motherboard.

According to another aspect of the invention, there is provided a method for manufacturing a semiconductor device, comprising the steps of mounting a lower package on a motherboard via lower terminals, and mounting an upper package on the lower package via intermediate terminals. The height of the lower terminals is designed such that the height before the lower and upper packages are mounted on the motherboard is equal to or greater than a degree of warping of the lower package before it is mounted on the motherboard and that the height after the lower and upper packages are mounted on the motherboard is equal to or smaller than the degree of warping of the lower package before it is mounted on the motherboard.

### BRIEF DESCRIPTION OF THE DRAWINGS

FIG. 1 is a cross-sectional view showing a semiconductor device according to a first embodiment of the present invention;

FIG. 2A is a plan view showing an upper package in the semiconductor device shown in FIG. 1;

FIG. 2B is a bottom view of the upper package;

FIG. 3A is a plan view showing a lower package in the semiconductor device shown in FIG. 1;

FIG. 3B is a bottom view of the lower package;

FIG. 4A is a cross-sectional view showing an upper package in a modified example of the semiconductor device according to the first embodiment of the invention;

FIG. 4B is a cross-sectional view showing a lower package in the modified example;

FIG. 5 is a chart for explaining a packaging temperature cycle test carried out in the first embodiment of the invention;

FIGS. 6A to 6C are cross-sectional views showing exemplary degrees of warping of the lower package on which a temperature cycle test of package simplex is carried out;

FIGS. 7A to 7C are cross-sectional views showing exemplary degrees of warping of the semiconductor device of the first embodiment of the invention;

FIGS. 8A to 8C are cross-sectional views showing exemplary degrees of warping of a semiconductor device tested by the packaging temperature cycle test;

FIG. 9 is a chart showing plastic strain caused in each intermediate terminal of the semiconductor device of the first embodiment of the invention and of a semiconductor device as a comparative example;

FIG. 10A is a cross-sectional view showing a lower package before it is stacked in a semiconductor device of a second embodiment of the invention;

FIG. 10B is a cross-sectional view showing the completed semiconductor device of the second embodiment;

FIGS. 11A to 11E are cross-sectional views explaining a method for manufacturing the semiconductor device of the second embodiment of the invention;

FIG. 12 is a cross-sectional view showing a semiconductor device according to a third embodiment of the invention; and

FIG. 13 is a cross-sectional view showing a semiconductor device according to a fourth embodiment of the invention.

### DESCRIPTION OF THE PREFERRED EMBODIMENT

A semiconductor device of the invention has a motherboard, a lower package mounted on the motherboard and an upper package mounted on the lower package.

Specifically, an edge portion of the lower package is in contact with the motherboard. It is noted that in the invention, the edge portions of the lower package refer to portions where intermediate terminals are disposed (overlap) within a marginal area of the lower package.

This structure restrains warping of the lower package and the upper packages mounted thereon which is otherwise caused by changes in temperature. As a result, stress and strain caused in the intermediate terminals formed between the lower and upper packages will be reduced, improving a packaging temperature cycle test.

Referring to the drawings, the semiconductor device of the invention will be described below in detail.

### First Embodiment

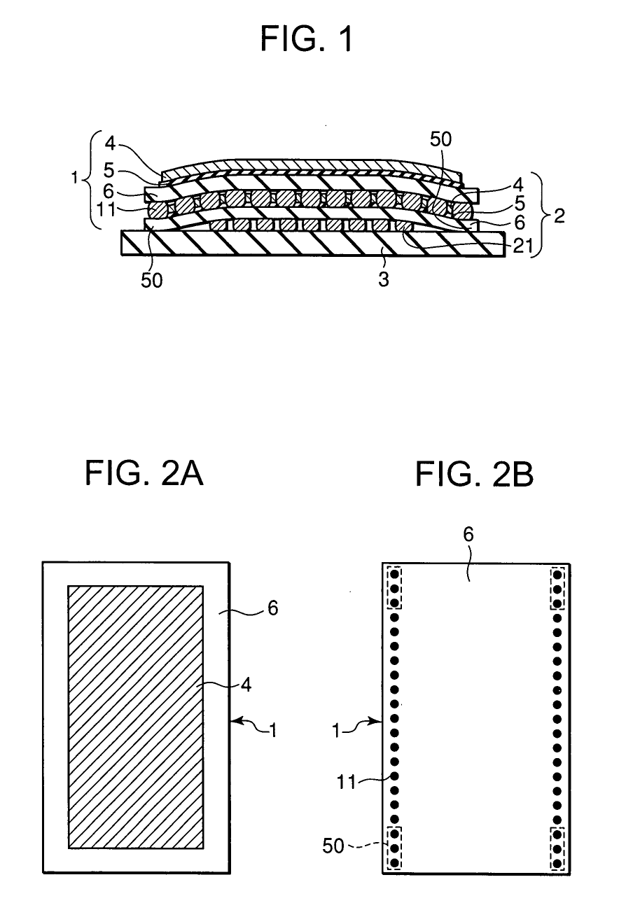

As seen in FIG. 1, the semiconductor device of a first embodiment of the invention has a motherboard 3, a lower package 2 mounted on the motherboard 3 via lower terminals 21 and an upper package 1 mounted on the lower package 2 via intermediate terminals 11.

Edge portions 50 of the lower package 2 are directly in contact with the motherboard 3. The edge portions 50 are portions within a marginal area of the lower package 2 where the intermediate terminals 11 are disposed (overlap).

The upper and lower packages 1 and 2 are semiconductor packages each having an interposer 6 and a chip 4 mounted on the interposer 6 via a mounting member 5.

A resin tape or resin substrate is used as the interposer 6. A material suitable for a method of mounting the chip 4 on the interposer 6 is selected as the mounting member 5 from among resin paste, a die attach film, an elastomer film, an under-fill film and the like.

Although not shown, a circuit pattern including lands is formed on the motherboard 3. Lands are formed at both sides of the interposer 6 of the lower package 2. The upper and lower lands are electrically connected through via-holes. Lands are formed also under the interposer 6 of the upper package 1.

The chip 4 of the lower package 2 is electrically connected with the lands on the motherboard 3 via via-holes not shown formed through the lower terminal 21 and the interposer 6. The chip 4 of the upper package 1 is electrically connected with the lands on the interposer 6 of the lower package 2 via via-holes not shown formed through the intermediate terminals 11 and the interposer 6. That is, the chip 4 of the upper package 1 is electrically connected with the lands on the motherboard 3 via the via-holes formed through the lower terminals 21 and the interposer 6 of the lower package 2 and the via-holes formed through the intermediate terminals 11 and the interposer 6 of the upper package 1.

Solder balls are used for the intermediate terminals 11 and the lower terminals 21.

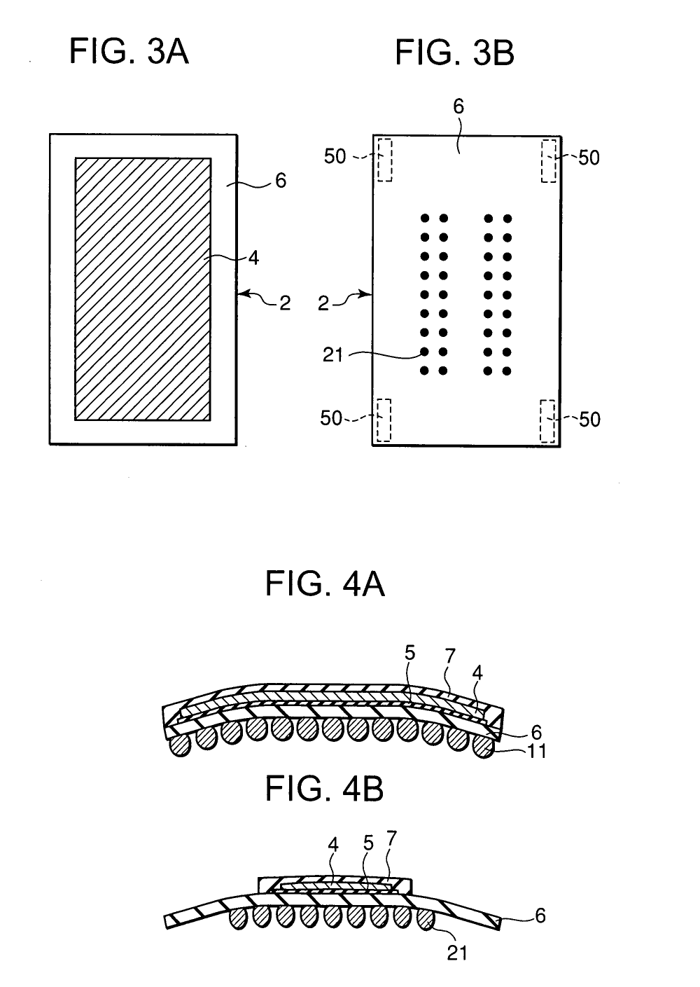

The intermediate terminals 11 are disposed on the land formed in an area not overlapping with the chip 4 on the lower face of the interposer 6 of the upper package 1 as shown in FIGS. 2A and 2B for example. The lower terminals 21 are disposed on the land in grid in the center part of the lower face of the interposer 6 of the lower package 2 as shown in FIGS. 3A and 3B for example. It is noted that the lower terminal 21 may not be always disposed at the area overlapping with the chip 4.

It is also noted that the lower and upper packages 2 and 1 may be a semiconductor package having the interposer 6, the chip 4 mounted on the interposer 6 via the mounting member 5 and a sealing resin 7 for covering the chip 4 together with the interposer 6 as shown in FIGS. 4A and 4B.

As shown in FIG. 1, the edge portions 50 of the lower package 2 are directly in contact with the motherboard 3 in this semiconductor device. It is noted that the edge portions 50 are not fixedly bonded but just in contact with the motherboard 3. The edge portions of the invention are not limited to four corners shown in FIGS. 2A and 2B and FIGS. 3A and 3B. It also includes both edge portions in a direction of warping such as a longitudinal direction of the lower package.

Next, an action and effect in improving a packaging temperature cycle life of the semiconductor device of the first embodiment will be explained.

A packaging temperature cycle test will be explained first.

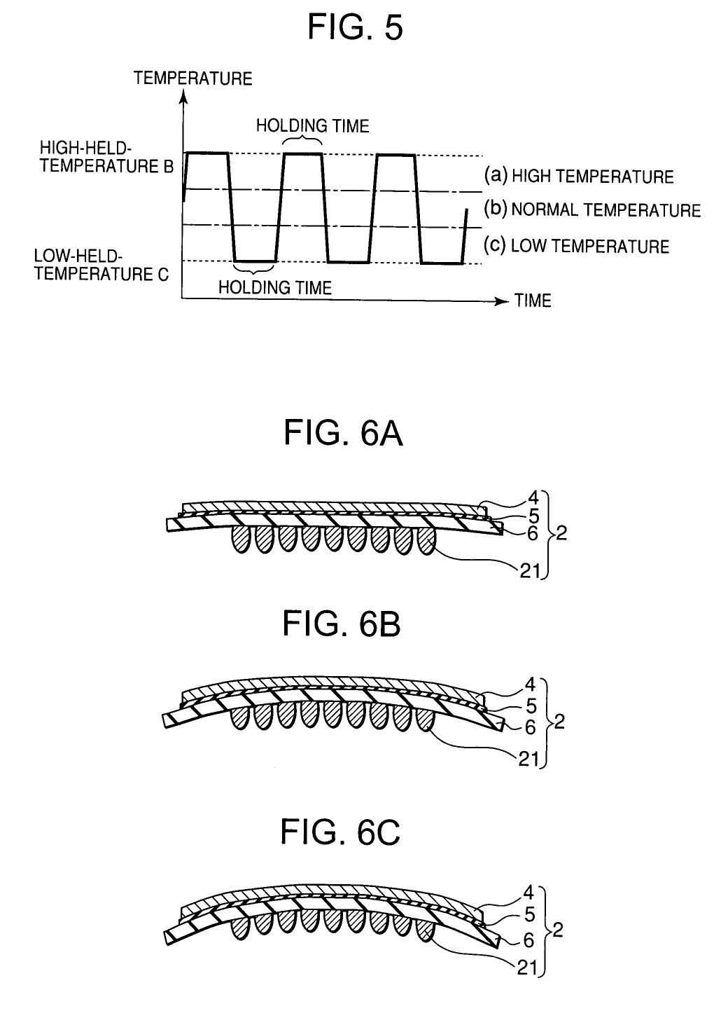

The packaging temperature cycle test of this embodiment is a load test in which the semiconductor device is exposed under an environment in which high and low temperature states are held alternately each for a predetermined time as shown in FIG. 5. Specifically, a high-temperature-side held temperature B is set at 100° C., a low-temperature-side held temperature C is set at −25° C. and each held time is set at 10 minutes. It is noted that in FIG. 5, a reference character (a) denotes a high temperature range, (b) a normal temperature range and (c) a low temperature range.

Prior to the packaging temperature cycle test, a temperature cycle test was carried on each simplex of the lower and upper packages 2 and 1 to be used in the semiconductor device shown in FIG. 1. The temperature cycle test was carried out under similar conditions to the packaging temperature cycle test described above.

FIGS. 6A to 6C show exemplary degrees of warping of the lower package 2 on which the temperature cycle test of the simplex of the lower package 2 was carried out. FIG. 6A shows a state in the high temperature range a, FIG. 6B shows a state in the normal temperature range b and FIG. 6C shows a state in the low temperature range c. A degree of warping of the lower package 2 increases in an upward convex-chip direction as the temperature changes from the high temperature range a to the low temperature range c through the normal temperature range b. This warping occurs because the interposer 6 whose coefficient of linear expansion is relatively larger than that of the chip 4 causes thermal contraction as the temperature changes. Although not shown, the upper package 1 is also warped in the same manner as the lower package 2. It is noted that the package composed of the interposer and the chip warps in almost the same manner as ones shown in FIGS. 6A to 6C even though there are some differences depending on physical properties of the materials composing the chip 4 and their thickness and thermal history during manufacturing.

Next, the packaging temperature cycle test was carried out on the semiconductor device of the present embodiment shown in FIG. 1.

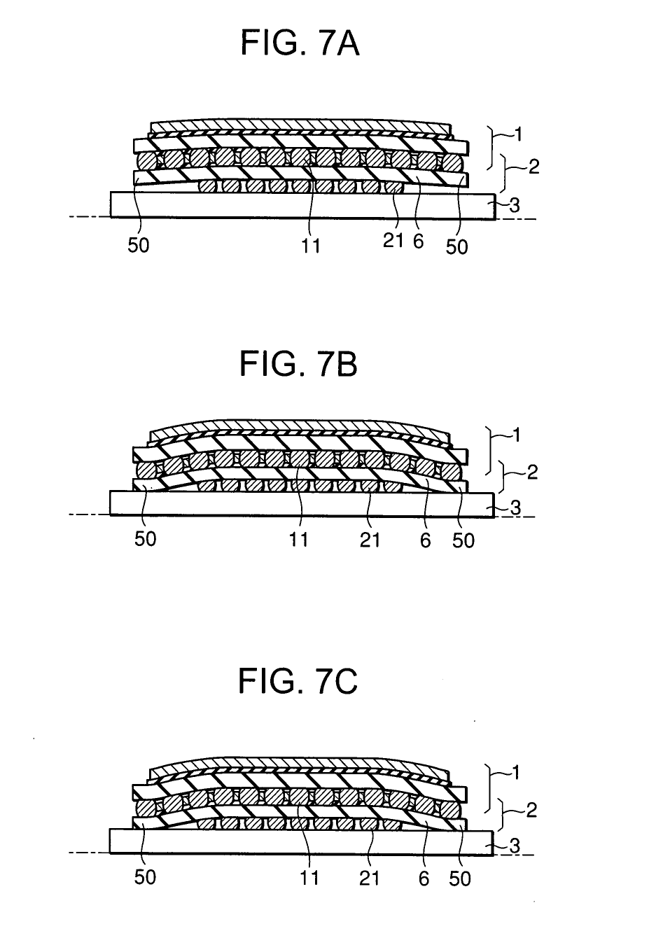

FIGS. 7A to 7C show exemplary degrees of warping of the semiconductor device caused by temperature. FIG. 7A shows a state in the high temperature range a, FIG. 7B shows a state in the normal temperature range b and FIG. 7C shows a state in the low temperature range c. A degree of warping of this semiconductor device increases in the upward convex-chip direction as the temperature changes from the high temperature range a to the low temperature range c through the normal temperature range b. This warping occurs because the warping direction of each simplex of the lower and upper packages 2 and 1 is reproduced even in the state in which they are stacked. It is noted that a mechanical interaction occurs among the motherboard 3, the lower package 2 and the upper package 1 because they are connected by the intermediate terminals 11 and the lower terminals 21. As a result, the shape and degree of warping of each of the lower and upper packages 2 and 1 in the semiconductor device do not always agree with the shape and degree of warping of the simplex of the package.

As it is apparent from FIGS. 7A to 7C, the increase in degree of warping of the semiconductor device is restricted in a region from the normal temperature range b to the low temperature range c because the edge portion 50 contacts the motherboard 3 in the normal temperature range b to the low temperature range c.

Next, the packaging temperature cycle test was carried out on a semiconductor device in which edge portions do not contact a motherboard as a comparative case.

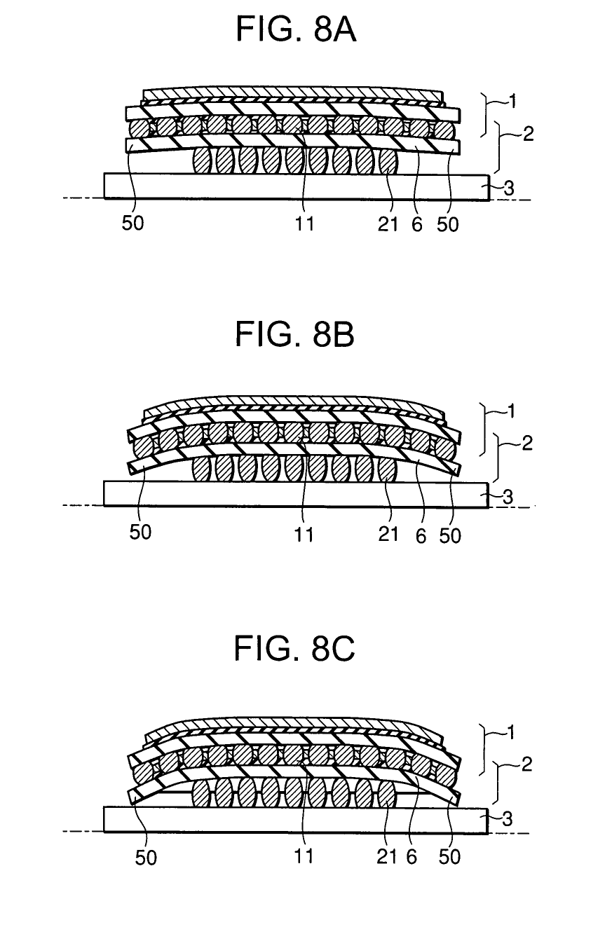

FIGS. 8A to 8C shows exemplary degrees of warping, caused by temperature, of the semiconductor device in which the edge portions 50 do not contact the motherboard 3. FIG. 8A shows a state in the high temperature range a, FIG. 8B shows a state in the normal temperature range b and FIG. 8C shows a state in the low temperature range c. The comparative semiconductor device is different from the semiconductor device of the present embodiment shown in FIGS. 7A to 7B in that the degree of warping still increases even in the region from the normal temperature range b to the low temperature range c.

The fact that the packaging temperature cycle life of the semiconductor device of the present embodiment is improved as compared with the comparative semiconductor device will be explained hereafter.

Because the package is a complex of non-organic and organic materials, stress and deformation can occur in each portion adjacent to the package due to temperature changes in the temperature cycle. In particular, stress caused in the intermediate terminal portion causes plastic strain in the intermediate terminals and the plastic strain accumulates due to the temperature being changed repeatedly. Rapture of the terminals advances in correspondence with this plastic strain, breaking the terminal in the end.

Attention is given to the intermediate terminals when the warping of each of the lower and upper packages is large. The stress caused in the intermediate terminals correlates with the degree of warping of the semiconductor device. An absolute degree of warping is large at the edge portions of the semiconductor device, so that the degree of the plastic strain of the intermediate terminals is large at the edge portions of the semiconductor device. That is, the rapture of the intermediate terminals at the edge portions of the semiconductor device advances quickly and the packaging temperature cycle life is shortened.

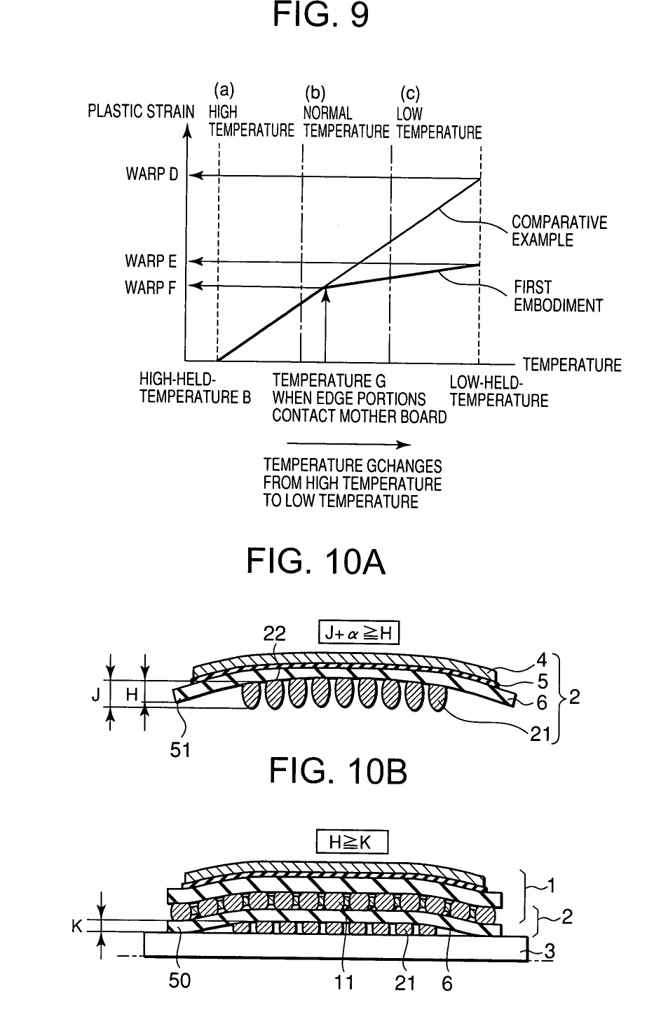

FIG. 9 is a schematic graph showing the increase in the plastic strain of the intermediate terminal with respect to the temperature changes from the high-temperature-side held temperature B to the low-temperature-side held temperature C.

In case of the comparative example whose edge portions do not contact the motherboard as shown in FIGS. 8A to 8C, the degree of warping continuously increases from the high-temperature side held temperature B to the low-temperature-side held temperature C and plastic strain D accumulates in correspondence with the increase of the degree of warping.

In case of the semiconductor device of the first embodiment whose edge portions contact the motherboard as shown in FIGS. 7A and 7B on the other hand, the degree of warping continuously increases in the same manner as in the comparative example and plastic strain F accumulates in correspondence with the increase of the degree of warping from the high-temperature-side held temperature B to temperature G at a time when the edge portions contact the motherboard. After that, the edge portions contact the motherboard and the warping does not increase from the temperature G to the low-temperature-side held temperature C, so that the stress caused in the intermediate terminals positioned above the edge portion also do not increase. Accordingly, a slope of accumulation of the plastic strain becomes moderate and only strain E is accumulated in the low-temperature-side held temperature C.

Because strain E<strain D, the semiconductor device of the first embodiment whose edge portions contact the motherboard has a packaging temperature cycle life that is longer than that of the semiconductor device of the comparative example whose edge portions do not contact the motherboard. This effect is significant, especially when the lower terminals of the lower package are unevenly distributed in the center part of the package and are not distributed in the peripheral part thereof.

### Second Embodiment

A semiconductor device of a second embodiment of the invention is different from that of the first embodiment in that its shape and dimension of each part are specified. Therefore, detailed explanation of the same or similar parts thereof with the first embodiment will be omitted here.

FIG. 10A shows a lower package in the semiconductor device of the second embodiment of the invention and FIG. 10B shows the semiconductor device of the second embodiment.

The semiconductor device of the second embodiment of the invention is designed as follows.

That is, a lower package 2 before it is mounted on the motherboard as shown in FIG. 10A is designed so that a sum of height J of a lower terminal 21 before mounting and thickness a of a temporary fixing member supplied to the motherboard in mounting the lower package 2 becomes equal to or more than a degree of deformation H of a edge portion 50 of the simplex of the lower package 2 in normal temperature. The degree of deformation H may be defined specifically as an absolute value of a difference between position 22 of an outermost lower terminal in a direction of an interposer Z among the lower terminals 21 in the simplex of the lower package 2 in normal temperature and position 51 of the edge portion 50 of the lower package 2 in the direction of the interposer Z. That is, the degree of deformation H corresponds to a degree of deformation of the edge portion 50 of the lower package 2 in the normal temperature.

J+α≧H

Furthermore, the semiconductor device in which the lower package 2 and the upper package 1 are mounted as shown in FIG. 10B is designed so that height K of the lower terminal 21 after mounting the lower package 2 and the upper package 1 becomes equal to or less than the degree of deformation H of the edge portion 50 of the simplex of the lower package 2 in the normal temperature.

K≦H

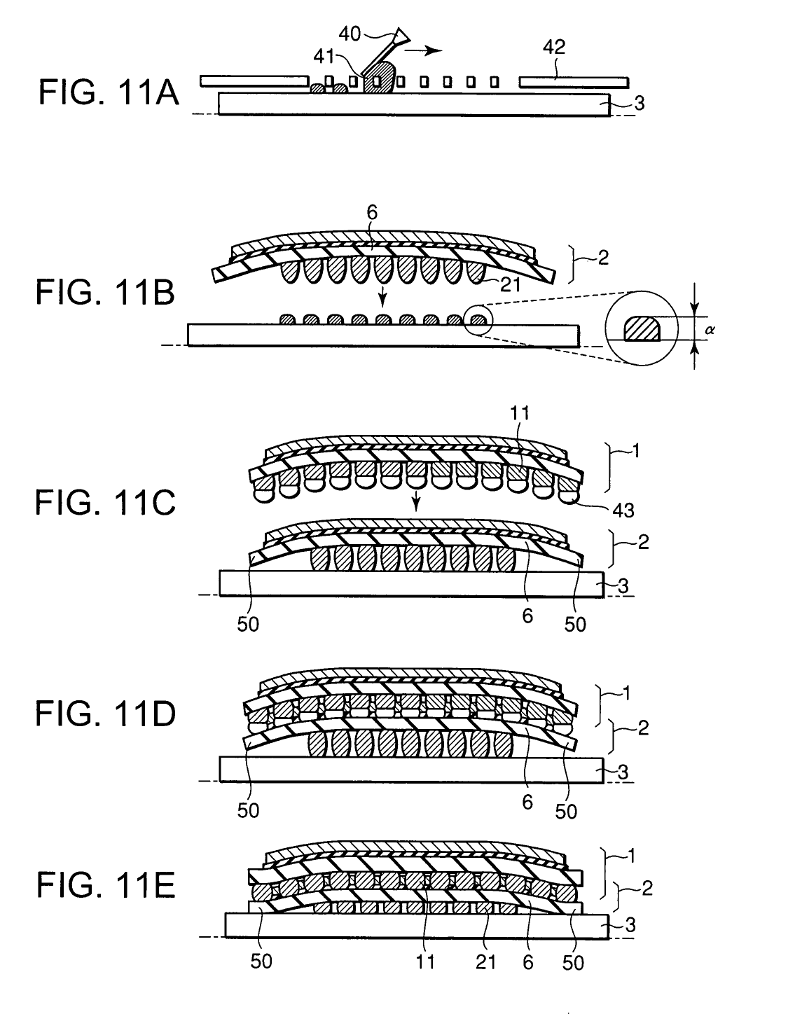

Next, a method for manufacturing the semiconductor device of the second embodiment of the invention whose shape and dimension are specified as described above will be explained with reference to FIGS. 11A to 11E.

A solder paste printing process is carried out as shown in FIG. 11A to form a temporary fixing member on the motherboard 3. Solder paste 41 is supplied to positions corresponding to the lower terminals 21 on the motherboard 3 via a printing metal mask 42 by actuating a squeegee. Although the solder paste printing process is adopted in this step, another method may be used. Flux may be also supplied instead of the solder paste 41. The solder paste and flux are materials necessary for terminal bonding, they have functions of temporarily fixing the mounted packages.

The lower package 2 is mounted on the motherboard 3 as shown in FIG. 11B. The temporary fixing member composed of solder paste 41 is formed at predetermined position of the motherboard 3. In the figure, α denotes a thickness of the temporary fixing member. The lower package 2 is mounted on the motherboard 3 such that the lower terminals 21 are aligned with the temporary fixing member by means of optical recognition for example.

The upper package 1 is mounted on the lower package 2 as shown in FIG. 11C. Flux 43 is supplied on the edge face of the intermediate terminals 11 of the upper package 1 by employing a flux transfer device or the like. The flux may be supplied on the lower terminals 21. Solder paste may be also supplied instead of the flux. Then, the upper package 1 is mounted on the lower package 2 so that the intermediate terminals 11 are aligned with predetermined position on an interposer of the lower package 2 by means of optical recognition for example.

Then, a reflow processing step is carried out as shown in FIG. 11D. The semiconductor device in which the upper package 1 is mounted on the lower package 2 is heated to equal to or more than melt temperature of solder and the semiconductor device of the second embodiment of the invention is completed as shown in FIG. 11E.

The lower package 2 is electrically connected with the upper package 1 via the intermediate terminals 11 in FIG. 11E. The lower package 2 is electrically connected with the motherboard 3 via the lower terminals 21.

The lower package 2 that meets J+α≧H in FIG. 10A can avoid the edge portions 50 of the interposer 6 of the lower package 2 from contacting the motherboard 3 in the step shown in FIG. 11C. Thereby, the effect of the temporary fixing member composed of the solder paste 41 is exhibited. As a result, it becomes possible to prevent misalignment of the lower package 2 in the series of steps shown in FIGS. 11B to 11D.

Furthermore, in the lower package 2 that meets K≦H in FIG. 10B, the edge portion 50 of the interposer 6 of the lower package 2 contacts directly to the motherboard 3 in the complete state in FIG. 11E. It then limits the increase of warping.

Accordingly, when it is assumed that H=about 200 μm and α is set at α=about 100 μm, the lower terminals are designed so that J≧about 100 μm and K≦about 200 μm.

The semiconductor device of the second embodiment exhibits the similar action and effect with the first embodiment and improves its packaging temperature cycle life.

### Third Embodiment

A semiconductor device of a third embodiment of the invention is different from the semiconductor device of the first embodiment in that a shape of a motherboard thereof is different. Accordingly, detailed explanation of the same or similar points thereof with the first embodiment will be omitted here.

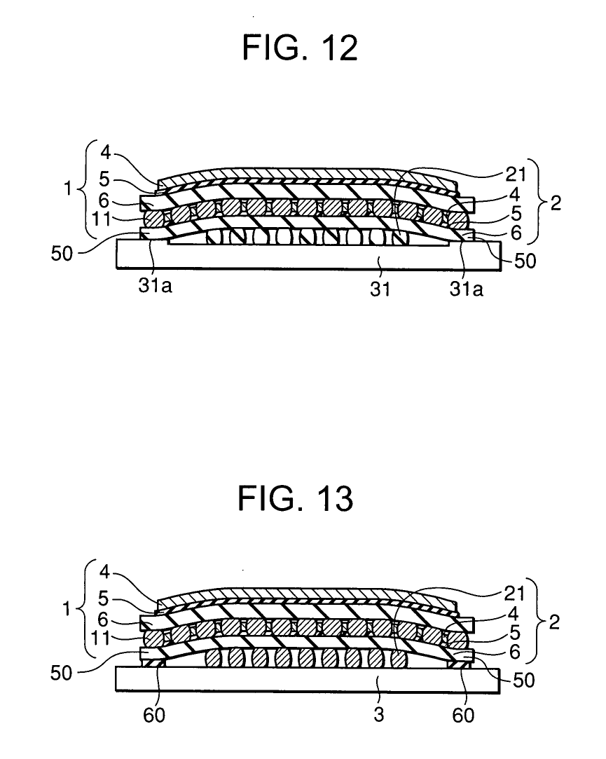

Referring to FIG. 12, the semiconductor device of the third embodiment of the invention has a motherboard 31, the lower package 2 mounted on the motherboard 31 and the upper package 1 mounted on the lower package 2.

Specifically, the motherboard 31 has convex portions 31a at positions corresponding to the edge portions 50 of the lower package 2. Height of the convex portion 31a is higher than position of the motherboard 31 facing to the lower terminals 21. The edge portions 50 of the lower package 2 are directly in contact with the convex portions 31a of the motherboard 3.

The semiconductor device of the third embodiment exhibits the similar action and effect with the first embodiment and improves its packaging temperature cycle life.

### Fourth Embodiment

A semiconductor device of a fourth embodiment of the invention is different from the semiconductor device of the first embodiment in that it has a spacer between a motherboard and edge portions of a lower package. Accordingly, detailed explanation of the same or similar points thereof with the first embodiment will be omitted here.

Referring to FIG. 13, the semiconductor device of the fourth embodiment of the invention has the motherboard 3, the lower package 2 mounted on the motherboard 3 and the upper package 1 mounted on the lower package 2.

Specifically, spacers 60 as support members are interposed between the motherboard 3 and the edge portions 50 of the lower package 2.

The spacers 60 are bonded to the positions of the motherboard 3 corresponding to the edge portions 50 of the lower package 2 or to the edge portions 50 of the lower package 2. Specifically, the spacers 60 are composed of a tape, solder resist (double resist) or solder. Or, the spacers 60 may be also one used as an electronic element such as a chip capacitor mounted on the motherboard.

Height of ceiling of the spacers 60 mounted on the motherboard 3 is higher than the position where the motherboard 3 faces with the lower terminal 21. A lower face of the spacer 60 bonded with the edge portion 50 of the lower package 2 is in contact with the motherboard 3.

The semiconductor device of the fourth embodiment exhibits the similar action and effect with the semiconductor device of the first embodiment and improves its packaging temperature cycle life.

It is needless to say that the invention is not limited to the embodiments described above and may be modified variously within the technological range described in the appended scope of claims.

What is claimed is:

1. A semiconductor device comprising:
a motherboard;
a lower package mounted on said motherboard; and
an upper package mounted on said lower package via intermediate terminals;
wherein an edge portion, in a marginal area of said lower package, with which said intermediate terminals overlaps is in contact with said motherboard.

2. The semiconductor device according to claim 1, wherein said lower package is mounted on said motherboard via lower terminals; and
height of said lower terminals is designed such that:
the height before said lower and upper packages are mounted on said motherboard is equal to or larger than a degree of warping of said lower package before it is mounted on said motherboard; and
the height after said lower and upper packages are mounted on said motherboard is equal to or smaller than the degree of warping of said lower package before it is mounted on said motherboard.

3. The semiconductor device according to claim 1, wherein said motherboard has a convex portion at position corresponding to said edge portion of said lower package, and
said edge portion of the said lower package is in contact with said convex portion of said motherboard.

4. The semiconductor device according to claim 1, further comprising a support member bonded to said motherboard at position corresponding to said edge portion of said lower package; wherein
said edge portion of said lower package is in contact with said motherboard via said support member.

5. The semiconductor device according to claim 1, further comprising a support member bonded to said edge portion of said lower package; wherein
said edge portion of said lower package is in contact with said motherboard via said support member.

6. A method for manufacturing a semiconductor device, comprising the steps of:
mounting a lower package on a motherboard via lower terminals; and
mounting an upper package on said lower package via intermediate terminals: wherein
height of said lower terminals is designed such that:
the height before said lower and upper packages are mounted on said motherboard is equal to or greater than a degree of warping of said lower package before it is mounted on said motherboard; and
the height after said lower and upper packages are mounted on said motherboard is equal to or smaller than the degree of warping of said lower package before it is mounted on said motherboard.
